(19) United States
(12) Patent Application Publication
(10) Pub. No.: US 2025/0324674 A1
(43) Pub. Date: Oct. 16, 2025

(54) MEMORY DEVICE AND MANUFACTURING METHOD THEREOF

(71) Applicant: UNITED MICROELECTRONICS CORP., Hsin-Chu City (TW)

(72) Inventors: Pei-Lun Jheng, Tainan City (TW); Chao-Sheng Cheng, Taichung City (TW); Po-Jui Chiang, Changhua County (TW); Ming-Jen Chang, Hsinchu City (TW); Ko-Chin Chang, Hsinchu City (TW); Yu-Ming Liu, Miaoli County (TW)

(73) Assignee: UNITED MICROELECTRONICS CORP., Hsin-Chu City (TW)

(21) Appl. No.: 18/675,174

(22) Filed: May 28, 2024

(30) Foreign Application Priority Data
Apr. 10, 2024 (TW) 113113217

(51) Int. Cl. H01L 29/423; H10B 41/10; H10B 41/30

(52) U.S. Cl. CPC H10D 30/6892; H10B 41/10; H10B 41/30

(57) ABSTRACT

A memory device includes a semiconductor substrate, a floating gate, and an erase gate. The floating gate and the erase gate are disposed above the semiconductor substrate, and the erase gate includes a main portion and a first branch portion. The main portion extends in a first horizontal direction, and the first branch portion extends in a second horizontal direction and is connected with the main portion. A first portion of the floating gate is located under the first branch portion in a vertical direction.

### BACKGROUND OF THE INVENTION

### 1. Field of the Invention

The present invention relates to a memory device and a manufacturing method thereof, and more particularly, to a memory device including an erase gate and a manufacturing method thereof.

### 2. Description of the Prior Art

Semiconductor memory devices are used in computer and electronics industries as a means for retaining digital information or data. Typically, the semiconductor memory devices are divided into volatile and non-volatile memory devices. The non-volatile memory devices, which can retain their data even when the power supply is interrupted, have been widely employed. As computer microprocessors become more and more powerful, the demands for memory (such as embedded memory) are also getting higher and higher. However, the manufacturing method and the structure of the embedded memory are easily affected by other devices formed on the chip and the designs thereof have to be integrated accordingly. Therefore, how to improve the operating performance of the memory devices through design changes in structure and/or manufacturing methods has always been a goal of the related industries.

### SUMMARY OF THE INVENTION

A memory device and a manufacturing method thereof are provided in the present invention. An erase gate including a branch portion is used to improve operation performance of the memory device.

According to an embodiment of the present invention, a memory device is provided. The memory device includes a semiconductor substrate, a floating gate, and an erase gate. The floating gate and the erase gate are disposed above the semiconductor substrate, and the erase gate includes a main portion and a first branch portion. The main portion extends in a first horizontal direction, and the first branch portion extends in a second horizontal direction and is connected with the main portion. A first portion of the floating gate is located under the first branch portion in a vertical direction.

According to an embodiment of the present invention, a manufacturing method of a memory device is provided. The manufacturing method includes the following steps. A semiconductor substrate is provided, and a floating gate and an erase gate are formed above the semiconductor substrate. The erase gate includes a main portion and a first branch portion. The main portion extends in a first horizontal direction, and the first branch portion extends in a second horizontal direction and is connected with the main portion. A first portion of the floating gate is located under the first branch portion in a vertical direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a memory device according to a first embodiment of the present invention.

FIG. 2 is a cross-sectional schematic drawing illustrating the memory device according to the first embodiment of the present invention.

FIG. 3 is another cross-sectional schematic drawing illustrating the memory device according to the first embodiment of the present invention.

FIG. 4 is further another cross-sectional schematic drawing illustrating the memory device according to the first embodiment of the present invention.

FIG. 5 is a partial enlarged schematic drawing illustrating the memory device according to the first embodiment of the present invention.

FIGS. 6-12 are schematic drawings illustrating a manufacturing method of a memory device according to an embodiment of the present invention, wherein FIG. 7 is a top view schematic drawing corresponding to FIG. 6, FIG. 8 is a schematic drawing in a step subsequent to FIG. 6, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, and FIG. 12 is a schematic drawing in a step subsequent to FIG. 11.

FIG. 13 is a schematic drawing illustrating a memory device according to a second embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

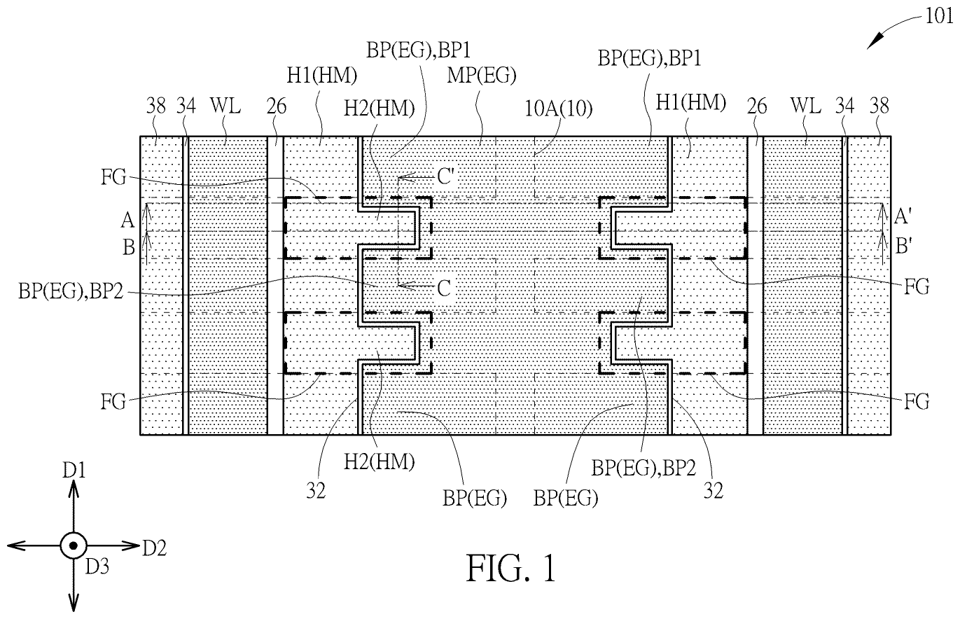

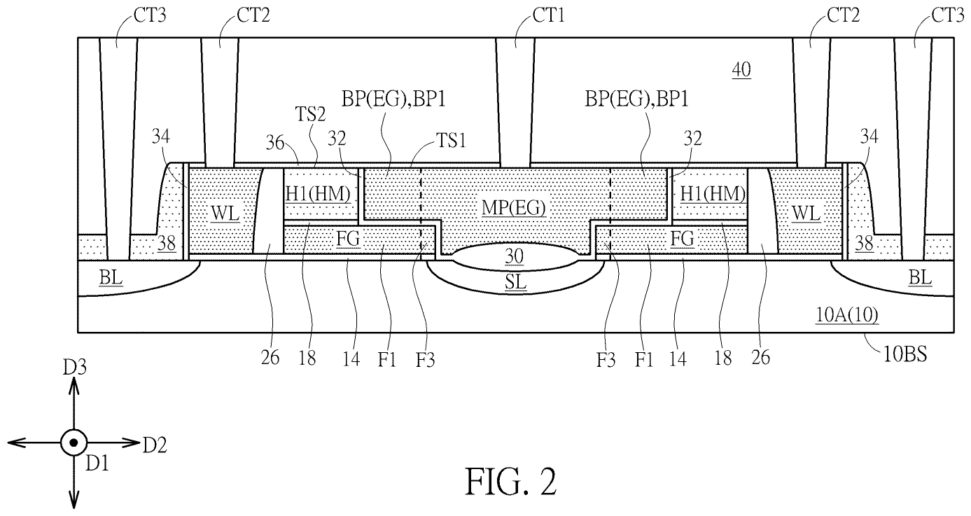

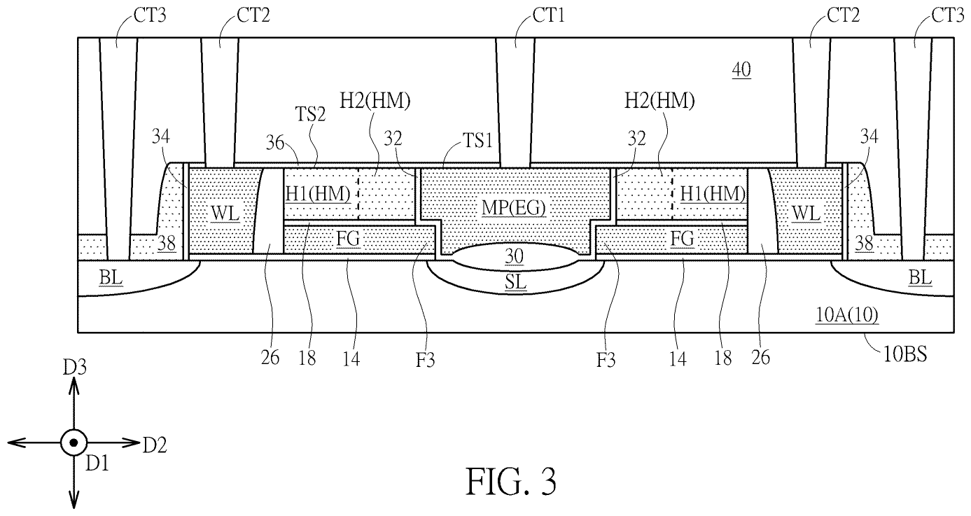

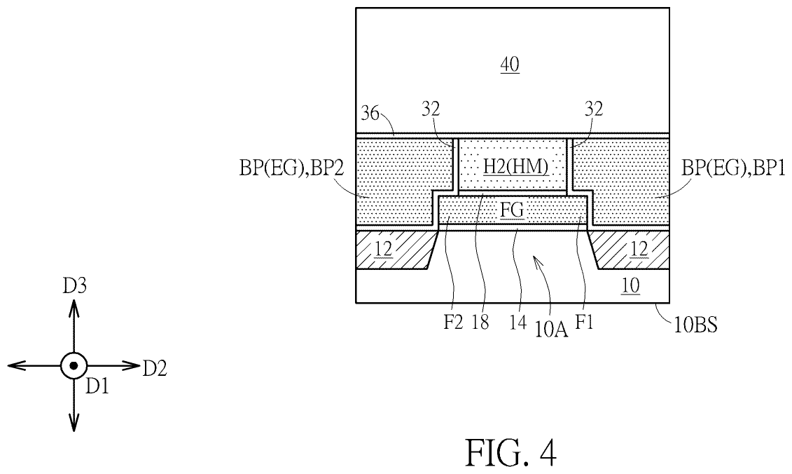

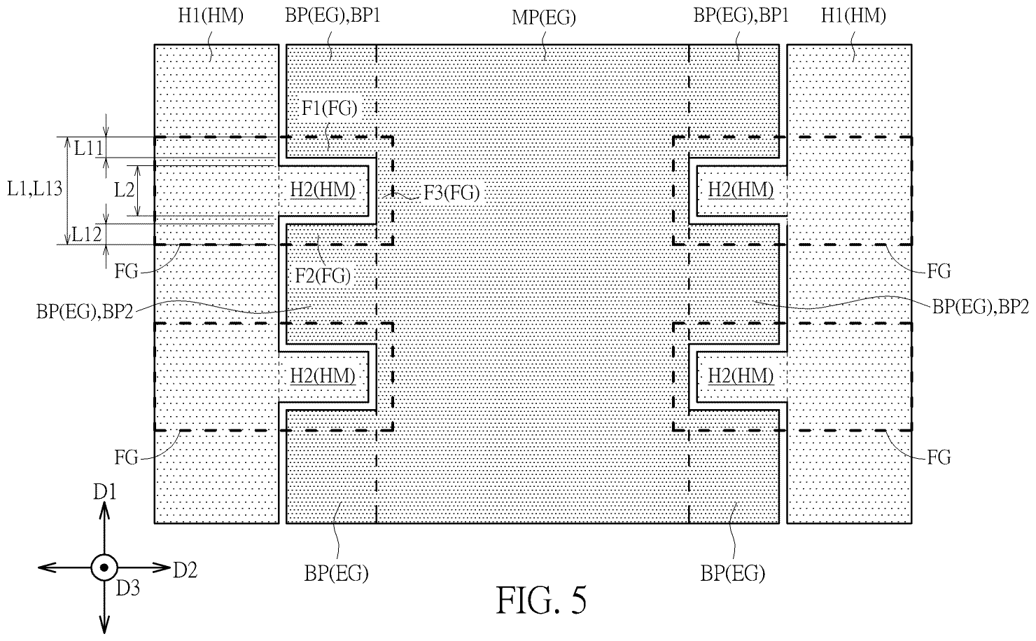

Please refer to FIGS. 1-5. FIG. 1 is a schematic drawing illustrating a memory device 101 according to a first embodiment of the present invention, FIG. 2 is a cross-sectional schematic drawing illustrating the memory device in this embodiment, FIG. 3 is another cross-sectional schematic drawing illustrating the memory device in this embodiment, FIG. 4 is further another cross-sectional schematic drawing illustrating the memory device in this embodiment, and FIG. 5 is a partial enlarged schematic drawing illustrating the memory device in this embodiment. FIG. 1 and FIG. 5 are top view schematic drawings of the memory device, FIG. 2 may be regarded as a cross-sectional diagram taken along a line A-A′ in FIG. 1, FIG. 3 may be regarded as a cross-sectional diagram taken along a line B-B′ in FIG. 1, and FIG. 4 may be regarded as a cross-sectional diagram taken along a line C-C′ in FIG. 1. However, in order to show the structural features in the top view diagrams more clearly, some components in the cross-sectional diagrams are not illustrated in the top view diagrams correspondingly. As shown in FIGS. 1-5, the memory device 101 includes a semiconductor substrate 10, a floating gate FG, and an erase gate EG. The floating gate FG and the erase gate EG are disposed above the semiconductor substrate 10, and the erase gate EG includes a main portion MP and a branch portion BP (such as a first branch portion BP1). The main portion MP extends in a first horizontal direction D1, and the first branch portion BP1 extends in a second horizontal direction D2 and is connected with the main portion MP. A first portion F1 of the floating gate FG is located under the first branch portion BP1 in a vertical direction D3. The area between the edge of the floating gate FG and the edge of the erase gate EG for generating electrical coupling and/or Fowler-Nordheim tunneling (F-N tunneling) may be increased by the design of the erase gate EG including the branch portion BP, and the programing speed and the erasing speed of the memory device 101 may by enhanced and/or the operation voltage of the memory device 101 may be reduced relatively for improving the operation window of the memory device 101 accordingly.

In some embodiments, the memory device 101 may include a plurality of the floating gates FG disposed separated from one another, the erase gate EG may include a plurality of the branch portions BP, and each of the branch portions BP may extend in the second horizontal direction D2 and be connected with the main portion MP directly. Some of the floating gates FG may be located at two opposite sides of the erase gate EG in the second horizontal direction D2, respectively, some of the branch portions BP may be located at two opposite sides of the main portion MP in the second horizontal direction D2, respectively, the erase gate EG may have a fishbone shape in the top view diagram of the memory device 101, and the first horizontal direction D1 may be substantially orthogonal to the second horizontal direction D2, but not limited thereto. In the top view diagram of the memory device 101, each of the floating gates FG may be disposed corresponding to two of the branch portions BP and partly overlap these two branch portions BP in the vertical direction D3, and the two branch portions BP located corresponding to the same floating gate FG may be regarded as the first branch portion BP1 and a second branch portion BP2, respectively. Therefore, the erase gate EG may include the second branch portion BP2 extending in the second horizontal direction D2 and connected with the main portion MP, and a second portion F2 of the floating gate FG may be located under the second branch portion BP2 in the vertical direction D3.

Specifically, the vertical direction D3 described above may be regarded as a thickness direction of the semiconductor substrate 10, the semiconductor substrate 10 may have a top surface and a bottom surface 10BS opposite to the top surface in the vertical direction D3, and the floating gate FG and the erase gate EG described above may be disposed at the side of the top surface. Horizontal directions substantially orthogonal to the vertical direction D3 (such as the first horizontal direction D1 and/or the second horizontal direction D2) may be substantially parallel with the top surface and/or the bottom surface 10BS of the semiconductor substrate 10, but not limited thereto. In this description, a distance between the bottom surface 10BS of the semiconductor substrate 10 and a relatively higher location and/or a relatively higher part in the vertical direction D3 may be greater than a distance between the bottom surface 10BS of the semiconductor substrate 10 and a relatively lower location and/or a relatively lower part in the vertical direction D3. The bottom or a lower portion of each component may be closer to the bottom surface 10BS of the semiconductor substrate 10 in the vertical direction D3 than the top or upper portion of this component. Another component disposed above a specific component may be regarded as being relatively far from the bottom surface 10BS of the semiconductor substrate 10 in the vertical direction D3, and another component disposed under a specific component may be regarded as being relatively close to the bottom surface 10BS of the semiconductor substrate 10 in the vertical direction D3, but not limited thereto. It is worth noting that, in this description, a top surface of a specific component may include the topmost surface of this component in the vertical direction D3, and a bottom surface of a specific component may include the bottommost surface of this component in the vertical direction D3, but not limited thereto. Additionally, in this description, the condition that a certain component is disposed between two other components in a specific direction may include but is not limited to a condition that the certain component is sandwiched between the two other components in the specific direction.

In some embodiments, the memory device 101 may further include a patterned mask layer HM disposed above the semiconductor substrate 10, the floating gate FG is partly disposed between the patterned mask layer HM and the semiconductor substrate 10 in the vertical direction D3, and the patterned mask layer HM may include a first portion H1 and a second portion H2. The first portion H1 may extend in the first horizontal direction D1, and the second portion H2 may extend in the second horizontal direction D2 and be connected with the first portion H1 of the patterned mask layer HM. In some embodiments, the memory device 101 may include two patterned mask layers HM located at two opposite sides of the erase gate EG in the second horizontal direction D2, respectively, each of the patterned mask layers HM may include a plurality of the second portions H2 connected with the first portion H, and each of the second portions H2 may extend towards the main portion MP of the erase gate EG in the second horizontal direction D2 from the edge of the first portion H1. In the top view diagram of the memory device 101, each of the first portions H1 may be disposed corresponding to and partly overlap a plurality of the floating gates FG in the vertical direction D3, each of the second portions H2 may be disposed corresponding to and partly overlap one of the floating gates FG in the vertical direction D3, and each of the second portions H2 may be sandwiched between two of the branch portions BP of the erase gate EG (such as the first branch portion BP1 and the second branch portion BP2) in the first horizontal direction D1.

In some embodiments, a part of the floating gate FG may be defined by the patterned mask layer HM and a spacer (not illustrated in FIGS. 1-5) on the sidewall of the patterned mask layer HM, and the areas of the first portion F1 and the second portion F2 of the floating gate FG will be influenced by the position of the second portion H2 of the patterned mask layer HM accordingly. For example, in the top view diagram of the memory device 101, when a central line of the second portion H2 in the first horizontal direction D1 overlaps a central line of the corresponding floating gate FG in the first horizontal direction D1, a length L11 of the first portion F1 of the floating gate FG in the first horizontal direction D1 may be substantially equal to a length L12 of the second portion F2 of the floating gate FG in the first horizontal direction D1. Comparatively, when alignment shifts occur in the process of forming the patterned mask layer HM, the length L11 of the first portion F1 of the floating gate FG in the first horizontal direction D1 will be different from the length L12 of the second portion F2 of the floating gate FG in the first horizontal direction D1. In addition, a length L2 of the second portion H2 of the patterned mask layer HM in the first horizontal direction D1 may be less than a length L1 of the floating gate FG in the first horizontal direction D1, a third portion F3 of the floating gate FG may be disposed under the main portion MP of the erase gate EG in the vertical direction D3, and a length L13 of the third portion F3 of the floating gate FG in the first horizontal direction D1 may be substantially equal to the length L1 of the floating gate FG in the first horizontal direction D1. Therefore, the length L13 of the third portion F3 of the floating gate FG in the first horizontal direction D1 may be greater than the length L11 of the first portion F1 of the floating gate FG in the first horizontal direction D1, the length L12 of the second portion F2 of the floating gate FG in the first horizontal direction D1, and the length L2 of the second portion H2 of the patterned mask layer HM in the first horizontal direction D1, respectively.

In some embodiments, the semiconductor substrate 10 may include a silicon substrate, an epitaxial silicon substrate, a silicon germanium substrate, a silicon carbide substrate, a silicon-on-insulator (SOI) substrate, or a semiconductor substrate made of other suitable semiconductor materials and/or made with other suitable structures. In addition, the memory device 101 may further include an isolation structure 12 disposed in the semiconductor substrate 10 for defining an active region 10A in the semiconductor substrate 10, the active region 10A may be a portion of the semiconductor substrate 10, and the material composition of the active region 10A may be the same as that of the semiconductor substrate 10 accordingly. The isolation structure 12 may include a single layer or multiple layers of insulation materials, such as an insulation liner layer and an insulation gap-filling material disposed on the insulation liner layer, but not limited thereto. In some embodiments, the active region 10A may include a first portion extending in the first horizontal direction D1 and a plurality of second portions crossing the first portion and extending in the second horizontal direction D2. The floating gate FG may be disposed on the second portion of the active region 10A, and the erase gate EG may be disposed on the active region 10A and the isolation structure 12. In some embodiments, the floating gate FG and the erase gate EG may be made of polycrystalline silicon or other suitable electrically conductive materials, the floating gate FG may be electrically floating without being directly connected to other electrically conductive materials, and the patterned mask layer HM may include a nitride insulation material (such as silicon nitride) or other suitable insulation materials. In some embodiments, a top surface TS1 of the erase gate EG and a top surface TS2 of the patterned mask layer HM may be substantially coplanar, and a control gate is not disposed in the memory device 101 additionally because the erase gate EG including the branch portion BP may replace the control gate for programing operation (such as using the portion of the erase gate EG overlapping the floating gate FG in the vertical direction D3 for generating electrical coupling), but not limited thereto.

In some embodiments, the memory device 101 may further include a source line region SL, a bit line region BL, a word line structure WL, a dielectric layer 14, a dielectric layer 18, a dielectric layer 26, a dielectric layer 30, a dielectric layer 32, a dielectric layer 34, a dielectric layer 36, a dielectric layer 38, a dielectric layer 40, and a plurality of contract structures (such as a contact structure CT1, contact structures CT2, and contact structures CT3). The source line region SL and the bit line region BL may be disposed in the semiconductor substrate 10, the source line region SL may be disposed corresponding to the erase gate EG in the vertical direction D3, and the source line region SL and the bit line region BL may be doped regions formed in the semiconductor substrate 10, such as n-type heavily doped regions, respectively, but not limited thereto. The dielectric layer 14, the dielectric layer 18, the dielectric layer 26, the dielectric layer 30, the dielectric layer 32, the dielectric layer 34, and the dielectric layer 36 may respectively include an oxide dielectric material or other suitable dielectric materials. A part of the dielectric layer 14 may be located between the floating gate FG and the semiconductor substrate 10 in the vertical direction D3, the dielectric layer 18 may be located between the patterned mask layer HM and the floating gate FG in the vertical direction D3, the dielectric layer 30 may be disposed between the erase gate EG and the source line region SL, and the dielectric layer 32 may be partly disposed between erase gate EG and the floating gate FG and partly disposed between the erase gate EG and the patterned mask layer HM. The word line structure WL and the dielectric layer 26 may be located on the dielectric layer 14, and the dielectric layer 26 may be partly located between the word line structure WL and the floating gate FG and partly located between the word line structure WL and the patterned mask layer HM. The dielectric layer 36 may cover the word line structure WL, the dielectric layer 26, the patterned mask layer HM, and the erase gate EG, the dielectric layer 38 may cover the bit line region BL and the sidewall of the word line structure WL, and the dielectric layer 34 may be located between the dielectric layer 38 and the word line structure WL. The dielectric layer 40 may cover the dielectric layer 36 and the dielectric layer 38. The contact structure CT1, the contact structure CT2, and the contact structure CT3 may penetrate through the corresponding dielectric layers for being electrically connected with the erase gate EG, the word line structure WL, and the bit line region BL, respectively. The dielectric layer 38 may include a nitride dielectric material or other suitable dielectric materials, and the dielectric layer 40 may include a single layer or multiple layers of dielectric materials, such as an oxide dielectric material, a nitride dielectric material, an oxynitride dielectric material, or other suitable dielectric materials. The word line structure WL may include polycrystalline silicon or other suitable electrically conductive materials, each of the contact structures may include a barrier layer and a low resistance material disposed on the barrier layer, the low resistance material may include a material with relatively low electrical resistivity, such as copper, aluminum, tungsten, and so forth, and the barrier layer may include titanium nitride, tantalum nitride, or other suitable electrically conductive barrier materials, but not limited thereto.

In some embodiments, the memory device 101 may include two patterned mask layers HM, two word line structures WL, and two bit line regions BL disposed at two opposite sides of the erase gate EG in the second horizontal direction D2, respectively, and the floating gates FG may be disposed at two opposite sides of the erase gate EG in the second horizontal direction D2, respectively. In addition, one of the floating gates FG and the erase gate EG, the word line structure WL, the source line region SL, the bit line region BL, the dielectric layer 26, the dielectric layer 30, and the dielectric layer 32 located corresponding to this floating gate FG may constitute a memory cell, and the erase gate EG may be shared by the memory cells located adjacent to each other in the first horizontal direction D1 and/or the memory cells located adjacent to each other in the second horizontal direction D2, but not limited thereto. In some embodiments, the memory device 101 may be regarded as an embedded flash memory (eflash) structure, and not providing control gate in the memory device 101 may improve the manufacturing process integration between the memory device 101 and other units formed on the semiconductor substrate 10, but not limited thereto. In addition, the erase gate EG including the branch portions BP in the present invention may also be applied to other types of memory devices according to some design considerations.

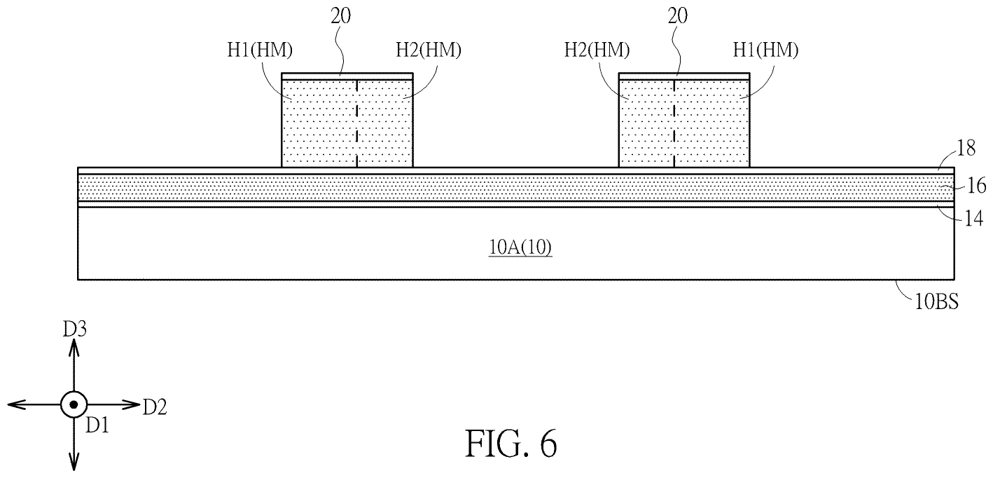

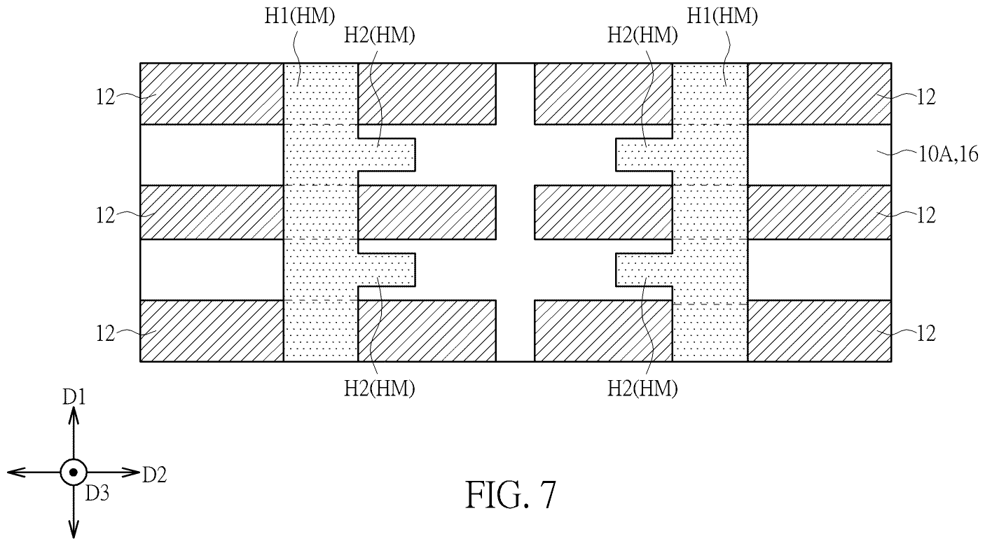

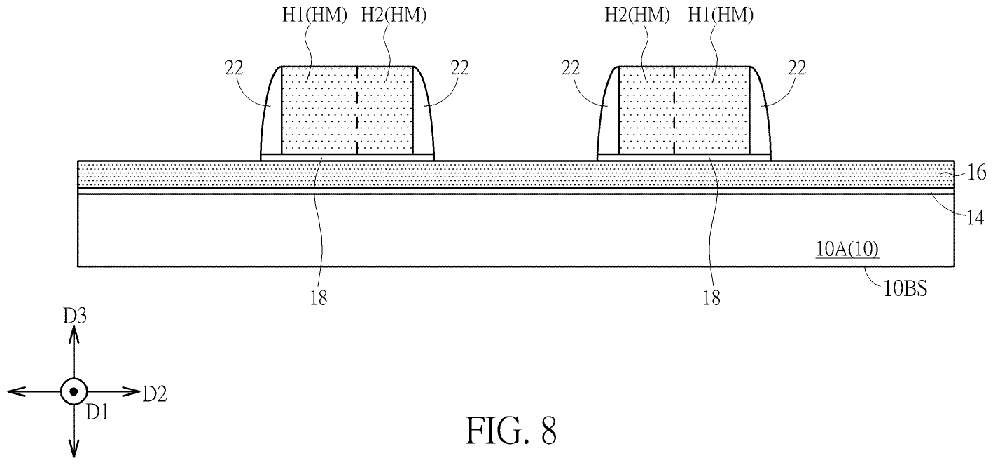

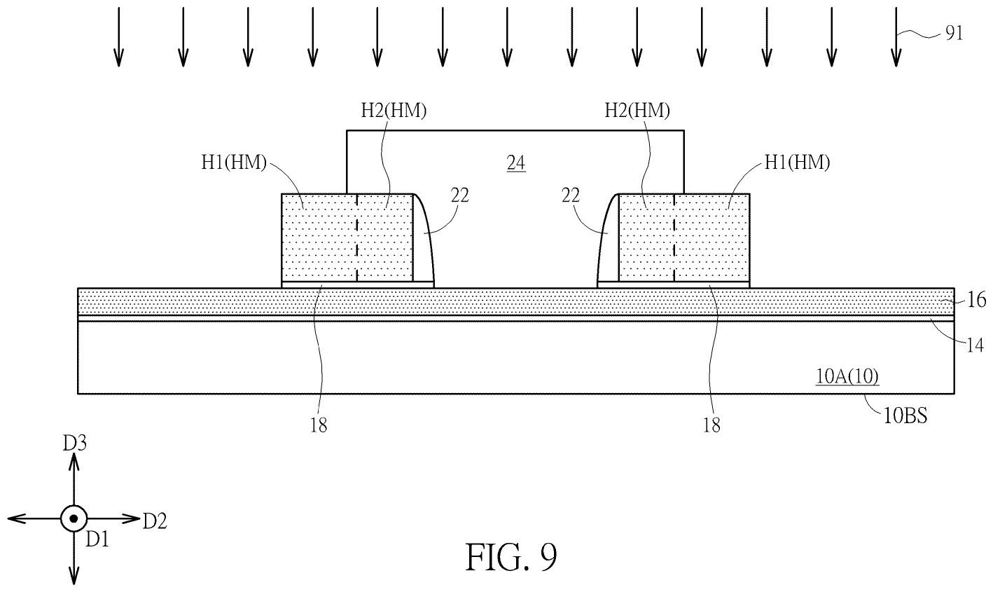

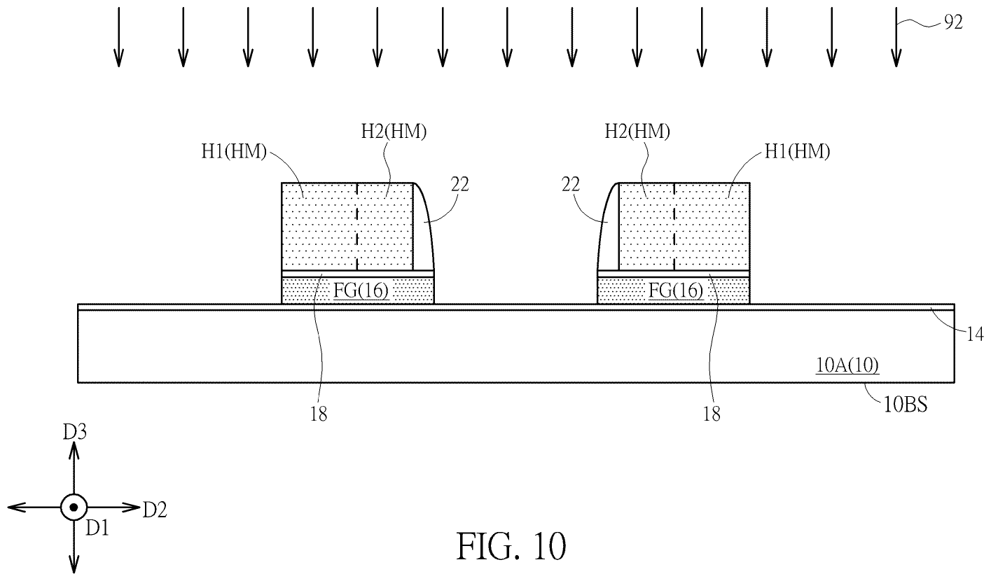

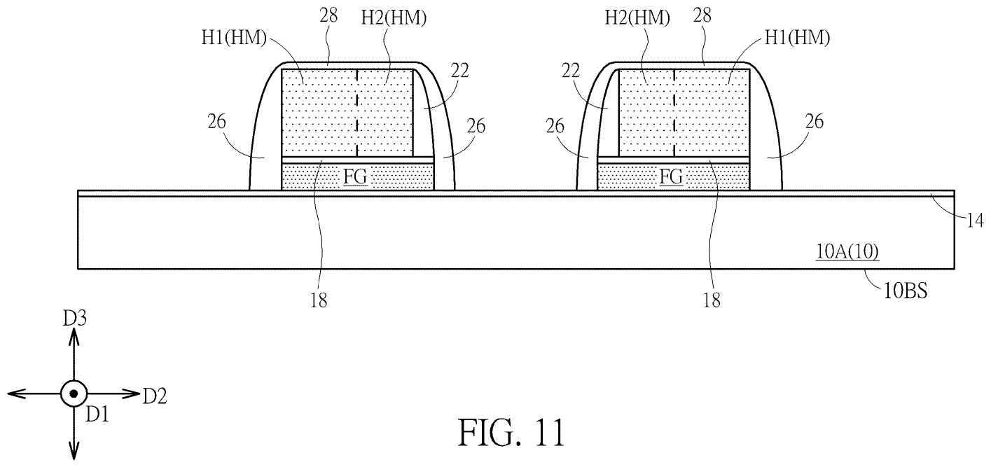

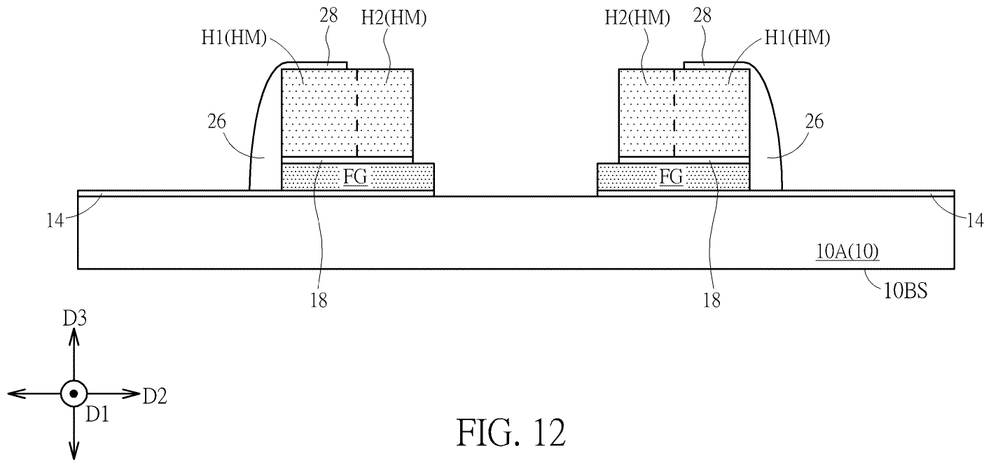

Please refer to FIGS. 6-12 and FIGS. 1-5. FIGS. 6-12 are schematic drawings illustrating a manufacturing method of a memory device according to an embodiment of the present invention, wherein FIG. 7 is a top view schematic drawing corresponding to FIG. 6, FIG. 8 is a schematic drawing in a step subsequent to FIG. 6, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, and FIG. 12 is a schematic drawing in a step subsequent to FIG. 11. In some embodiments, FIG. 3 may be regarded as a schematic drawing in a step subsequent to FIG. 12, but not limited thereto. In addition, in order to show the structural features in the top view diagram (FIG. 7) more clearly, some components in FIG. 6 are not illustrated in the top view diagram correspondingly. As shown in FIGS. 1-5, the manufacturing method in this embodiment may include the following steps. The semiconductor substrate 10 is provided, and the floating gate FG and the erase gate EG are formed above the semiconductor substrate 10. The erase gate EG includes the main portion MP and the first branch portion BP1. The main portion MP extends in the first horizontal direction D1, and the first branch portion BP1 extends in the second horizontal direction D2 and is connected with the main portion MP. The first portion F1 of the floating gate FG is located under the first branch portion BP1 in the vertical direction D3.

Specifically, the manufacturing method in this invention may include but is not limited to the following steps. As shown in FIG. 6 and FIG. 7, the dielectric layer 14, a patterned material layer 16, and the dielectric layer 18 may be formed above the semiconductor substrate 10, and the patterned mask layer HM and the dielectric layer 20 may be formed above the semiconductor substrate 10 after the patterned material layer 16 is formed. In some embodiments, the isolation structure 12 may be formed in the semiconductor substrate 10 for defining the active region 10A in the semiconductor substrate 10, and the isolation structure 12 may be formed by forming a trench in the semiconductor substrate 10 and filling the trench with insulation materials. Additionally, the dielectric layer 14, the dielectric layer 18 and the material layer sandwiched between the dielectric layer 14 and the dielectric layer 18 may be patterned together by the process of forming the trench described above. Therefore, the material layer sandwiched between the dielectric layer 14 and the dielectric layer 18 may be patterned to become the patterned material layer 16, and the patterned material layer 16 may be located corresponding to the active region 10A in the vertical direction D3 substantially, but not limited thereto. In addition, the patterned mask layer HM may include the first portion H1 and the second portion H2 described above, the second portion H2 may be formed above the active region 10A and the patterned material layer 16 in the vertical direction D3, and the first portion H1 may be formed above the isolation structure 12 and the patterned material layer 16. Therefore, the patterned mask layer HM may be partly formed above the patterned material layer 16 in the vertical direction D3 and partly formed above the isolation structure 12 in the vertical direction D3.

As shown in FIG. 6 and FIG. 8, a spacer 22 may be formed on a sidewall of the patterned mask layer HM, and the spacer 22 may include an oxide dielectric material or other suitable dielectric materials. In some embodiments, the dielectric layer 20 and a part of the dielectric layer 18 may be removed by an etching process of forming the spacer 22 (such as a dry etching process, but not limited thereto), and a part of the patterned material layer 16 may be exposed accordingly, but not limited thereto. Subsequently, as shown in FIG. 8 and FIG. 9, a removing process 91 may be performed for removing a part of the spacer 22, and another part of the spacer 22 may remain on a sidewall of the second portion H2 of the patterned mask layer HM after the removing process 91. In some embodiments, a patterned mask layer 24 may be formed on the semiconductor substrate 10 before the removing process 91, and the patterned mask layer 24 may cover the spacer 22 located on the sidewall of the second portion H2 of the patterned mask layer HM and at least a part of the patterned mask layer HM. In some embodiments, the removing process 91 may include an etching process (such as a wet cleaning process, but not limited thereto), the patterned mask layer 24 may be used as an etching mask in this etching process, and the patterned mask layer 24 may include patterned photoresist or other suitable mask materials. As shown in FIG. 9 and FIG. 10, after the removing process 91, the patterned mask layer 24 may be removed, an etching process 92 using the patterned mask layer HM and the spacer 22 (such as the spacer 22 located on the sidewall of the second portion H2 of the patterned mask layer HM) as a mask may be performed to the patterned material layer 16, and at least a part of the patterned material layer 16 may be etched to become the floating gate FG by the etching process 92. In other words, the removing process 91 is performed before the etching process 92, and a projection pattern of the floating gate FG in the vertical direction D3 will be influenced by the shapes of the patterned mask layer HM and the spacer 22 and the position where the patterned mask layer HM and the spacer 22 are formed. It is worth noting that the method of forming the floating gate FG in this invention may include but is not limited to the steps shown in FIGS. 6-10 described above, and the floating gate FG may be formed by other suitable approaches according to some design considerations.

As shown in FIG. 11, after the step of forming the floating gate FG, the dielectric layer 26 may be formed on the sidewalls of the patterned mask layer HM and the floating gate FG, and the dielectric layer 26 may be regarded as a spacer formed on the sidewalls. In some embodiments, the dielectric layer 26 may be formed by forming a dielectric material and performing an etching back process to this dielectric material, and a dielectric layer 28 may be formed on the patterned mask layer HM. As shown in FIG. 11 and FIG. 12, the spacer remaining on the sidewall of the second portion H2 of the patterned mask layer HM, a part of the dielectric layer 26, a part of the dielectric layer 28, and a part of the dielectric layer 14 may then be removed for exposing a part of the active region 10A. Subsequently, as shown in FIG. 3 and FIG. 1, the erase gate EG, the source line region SL, the bit line region BL, the word line structure WL, the dielectric layer 30, the dielectric layer 32, the dielectric layer 34, the dielectric layer 36, the dielectric layer 38, the dielectric layer 40, and the contact structures described above may be formed for forming the memory device 101. In other words, the spacer 22 remaining on the sidewall of the second portion H2 of the patterned mask layer HM may be removed after the etching process 92 shown in FIG. 10 and before the erase gate EG is formed. In some embodiments, the method of forming the erase gate EG and the word line structure WL may include performing a planarization process (such as a chemical mechanical polishing process, but not limited thereto) to an electrically conductive material (such as polycrystalline silicon, but not limited thereto) formed on the semiconductor substrate 10. The dielectric layer 28 illustrated in FIG. 12, a part of the patterned mask layer HM, and a part of the dielectric layer 26 may be removed by this planarization process, and the top surface TS of the erase gate EG, the top surface TS2 of the patterned mask layer HM, and a top surface of the word line structure WL may be substantially coplanar, but not limited thereto.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

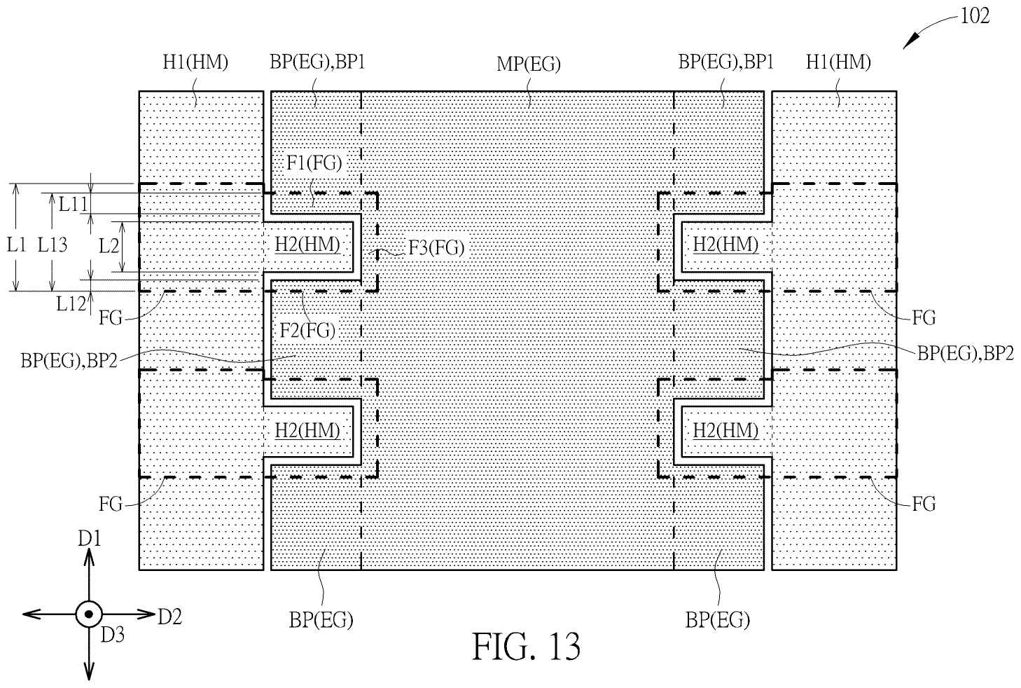

Please refer to FIG. 13. FIG. 13 is a schematic drawing illustrating a memory device 102 according to a second embodiment of the present invention. As shown in FIG. 13, in the memory device 102, the length L11 of the first portion F1 of the floating gate FG in the first horizontal direction D1 may be different from the length L12 of the second portion F2 of the floating gate FG in the first horizontal direction D1. For example, when the position where the patterned mask layer HM is formed shifts towards the lower portion of FIG. 13 in the first horizontal direction D1, the length L11 of the first portion F1 in the first horizontal direction D1 labeled in FIG. 13 may be greater than the length L12 of the second portion F2 in the first horizontal direction D1 labeled in FIG. 13, but not limited thereto. In addition, the floating gate FG may be influenced by the position where the patterned mask layer HM is formed, the length L1 of the floating gate FG in the first horizontal direction D1 may be regarded as the maximum length of the floating gate FG in the first horizontal direction D1, and the length L13 of the third portion F3 of the floating gate FG in the first horizontal direction D1 may be less than the length L1, but not limited thereto.

To summarize the above descriptions, according to the memory device and the manufacturing method thereof in the present invention, the erase gate including the branch portion may be used to increase the area between the edge of the floating gate and the edge of the erase gate for generating electrical coupling and/or F-N tunneling, and the programing speed and the erasing speed of the memory device may by enhanced and/or the operation voltage of the memory device may be reduced relatively for improving the operation window of the memory device accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory device, comprising:
a semiconductor substrate;
a floating gate disposed above the semiconductor substrate; and
an erase gate disposed above the semiconductor substrate, wherein the erase gate comprises:
a main portion extending in a first horizontal direction; and
a first branch portion extending in a second horizontal direction and connected with the main portion, wherein a first portion of the floating gate is located under the first branch portion in a vertical direction.

2. The memory device according to claim 1, wherein the erase gate further comprises:
a second branch portion extending in the second horizontal direction and connected with the main portion, wherein a second portion of the floating gate is located under the second branch portion in the vertical direction.

3. The memory device according to claim 2, wherein a length of the first portion of the floating gate in the first horizontal direction is different from a length of the second portion of the floating gate in the first horizontal direction.

4. The memory device according to claim 2, further comprising:
a patterned mask layer disposed above the semiconductor substrate, wherein the floating gate is partly disposed between the patterned mask layer and the semiconductor substrate in the vertical direction, and the patterned mask layer comprises:
a first portion extending in the first horizontal direction; and
a second portion extending in the second horizontal direction and connected with the first portion of the patterned mask layer, wherein the second portion of the patterned mask layer is sandwiched between the first branch portion of the erase gate and the second branch portion of the erase gate in the first horizontal direction.

5. The memory device according to claim 4, wherein a length of the second portion of the patterned mask layer in the first horizontal direction is less than a length of the floating gate in the first horizontal direction.

6. The memory device according to claim 4, wherein a third portion of the floating gate is disposed under the main portion of the erase gate in the vertical direction.

7. The memory device according to claim 6, wherein a length of the third portion of the floating gate in the first horizontal direction is greater than a length of the first portion of the floating gate in the first horizontal direction and a length of the second portion of the floating gate in the first horizontal direction.

8. The memory device according to claim 6, wherein a length of the third portion of the floating gate in the first horizontal direction is greater than a length of the second portion of the patterned mask layer in the first horizontal direction.

9. The memory device according to claim 4, wherein a top surface of the erase gate and a top surface of the patterned mask layer are coplanar.

10. The memory device according to claim 1, wherein the first horizontal direction is orthogonal to the second horizontal direction.

11. A manufacturing method of a memory device, comprising:
providing a semiconductor substrate;
forming a floating gate above the semiconductor substrate; and
forming an erase gate disposed above the semiconductor substrate, wherein the erase gate comprises:
a main portion extending in a first horizontal direction; and
a first branch portion extending in a second horizontal direction and connected with the main portion, wherein a first portion of the floating gate is located under the first branch portion in a vertical direction.

12. The manufacturing method of the memory device according to claim 11, wherein a method of forming the floating gate comprises:
forming a patterned material layer above the semiconductor substrate;
forming a patterned mask layer above the semiconductor substrate after the patterned material layer is formed, wherein the patterned mask layer is partly formed above the patterned material layer in the vertical direction;
forming a spacer on a sidewall of the patterned mask layer; and
performing an etching process using the patterned mask layer and the spacer as a mask to the patterned material layer, wherein at least a part of the patterned material layer is etched to become the floating gate by the etching process.

13. The manufacturing method of the memory device according to claim 12, wherein the patterned mask layer comprises:
a first portion extending in the first horizontal direction; and
a second portion extending in the second horizontal direction and connected with the first portion of the patterned mask layer.

14. The manufacturing method of the memory device according to claim 13, wherein the method of forming the floating gate further comprising:
performing a removing process for removing a part of the spacer before the etching process, wherein another part of the spacer remains on a sidewall of the second portion of the patterned mask layer after the removing process.

15. The manufacturing method of the memory device according to claim 14, further comprising:
removing the another part of the spacer remaining on the sidewall of the second portion of the patterned mask layer after the etching process and before the erase gate is formed.

16. The manufacturing method of the memory device according to claim 13, wherein a length of the second portion of the patterned mask layer in the first horizontal direction is less than a length of the floating gate in the first horizontal direction.

17. The manufacturing method of the memory device according to claim 13, wherein the erase gate further comprises:
a second branch portion extending in the second horizontal direction and connected with the main portion, wherein a second portion of the floating gate is located under the second branch portion in the vertical direction.

18. The manufacturing method of the memory device according to claim 17, wherein the second portion of the patterned mask layer is sandwiched between the first branch portion of the erase gate and the second branch portion of the erase gate in the first horizontal direction.

19. The manufacturing method of the memory device according to claim 17, wherein a length of the first portion of the floating gate in the first horizontal direction is different from a length of the second portion of the floating gate in the first horizontal direction.

20. The manufacturing method of the memory device according to claim 11, wherein the first horizontal direction is orthogonal to the second horizontal direction.
